(19) United States
(12) Patent Application Publication
(10) Pub. No.: US 2026/0164746 A1
(43) Pub. Date: Jun. 11, 2026

(54) BIDIRECTIONAL SEMICONDUCTOR SWITCH WITH SEPERATE REFERENCE POTENTIAL CONNECTION FOR FIELD PLATE

(71) Applicant: Infineon Technologies Austria AG, Villach (AT)

(72) Inventors: Gerhard Prechtl, Rosegg (AT); Luca Sayadi, Villach (AT); Oliver Häberlen, Villach (AT)

(21) Appl. No.: 19/263,920

(22) Filed: Jul. 9, 2025

Related U.S. Application Data
(60) Provisional application No. 63/730,706, filed on Dec. 11, 2024.

(51) Int. Cl. H10D 64/00; H01L 23/528; H03K 17/687; H10D 30/47; H10D 62/10; H10D 62/824

(52) U.S. Cl. CPC H10D 64/111; H03K 17/687; H10D 30/475; H10D 62/103; H10D 62/824; H10W 20/427; H10W 20/43

(57) ABSTRACT

A semiconductor device includes a semiconductor body having an active region and a substrate region beneath the active region, a bidirectional switch including first and second input-output terminals, a gate structure configured to control a conduction state of a channel within the active region, the gate structure comprising one or more gate electrodes, and a field plate structure configured to influence electric field distribution between the gate structure and each of the first and second input-output terminals, the field plate structure comprising a field plate that extends over access regions on either side of the one or more gate electrodes, a secondary circuit configured to generate a quasi-reference potential in both an on-state and an off-state of the bidirectional switch at a first node of the secondary circuit, and a quasi-reference potential connection that directly connects the field plate to the first node.

### BACKGROUND

Bidirectional switches, i.e., switching devices that can control current flowing in two directions, offer many advantageous electrical properties which make them useful in a wide array of applications. One bidirectional switch configuration is a so-called common drain configuration that comprises two separate gates arranged between source/drain terminals at either side of the device. Another type of bidirectional switch configuration is a so-called common source configuration that comprises a single gate arranged between two source/drain terminals at either side of the gate structure. The common source configuration may be preferred in lower voltage applications, e.g., applications involving the application of no greater than 300V, 100V, 50V, 25V or less, due to space efficiency considerations. Bidirectional switches may include conductive field plates to shape electrical fields in access regions of the device. These field plates are set at a low potential, such as a ground potential. In the case of a common source configured device, it becomes challenging to set the potential of the field plate at the source potential because the device terminal which acts as the source terminal changes depending on the operational state of the device. Although the field plate can be connected with the gate potential, this arrangement leads to large C_{gd} (gate-drain capacitance) values, which is especially detrimental for fast switching applications, for example.

Accordingly, a solution for maintaining the field plate at a low potential in all operational states of a bidirectional device is needed.

### SUMMARY

A semiconductor device is disclosed. According to an embodiment, the semiconductor device comprises a semiconductor body comprising an active region and a substrate region beneath the active region, a bidirectional switch comprising first and second input-output terminals, a gate structure configured to control a conduction state of a channel within the active region between the first and second input-output terminals, the gate structure comprising one or more gate electrodes, and a field plate structure configured to influence electric field distribution between the gate structure and each of the first and second input-output terminals, the field plate structure comprising a field plate for each of the one or more gate electrodes that extends over access regions on either side of the one or more gate electrodes, a secondary circuit configured to generate a quasi-reference potential in both an on-state and an off-state of the bidirectional switch at a first node of the passive circuit, and a quasi-reference connection that directly connects the field plate to the first node. Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a circuit schematic of an embodiment of a semiconductor device that includes a bidirectional switch and a secondary circuit that provides a quasi-reference potential in all states of the bidirectional switch.

FIG. 2 illustrates a cross-sectional view of an embodiment of the physical implementation of a bidirectional switch in a semiconductor body wherein the reference potential is connected to the substrate and the field plate along with a circuit schematic of the secondary circuit.

FIG. 3 illustrates a plan-view layout of a portion of a semiconductor device comprising a bidirectional switch, according to an embodiment.

FIG. 4 illustrates a plan-view layout of a portion of a semiconductor device comprising a bidirectional switch, according to an embodiment.

FIG. 5 illustrates a plan-view layout of a portion of a semiconductor device comprising a bidirectional switch, according to an embodiment.

FIG. 6, which includes FIGS. 6A and 6B, illustrates a plan-view layout of a portion of a semiconductor device comprising a bidirectional switch, according to an embodiment. FIG. 6A illustrates an overall view of an active area comprising the bidirectional switch; and FIG. 6B illustrates a close-up view of a via connection with a gate electrode.

FIG. 7 illustrates a plan-view layout of a portion of a semiconductor device comprising a bidirectional switch, according to an embodiment.

FIG. 8 illustrates a plan-view layout of a portion of a semiconductor device comprising a bidirectional switch and a secondary circuit, according to an embodiment.

FIG. 9 illustrates a plan-view layout of a portion of a semiconductor device comprising a bidirectional switch and a secondary circuit, according to an embodiment.

### DETAILED DESCRIPTION

Embodiments of a semiconductor device that includes a bidirectional switch with a common-source configuration are described herein. The bidirectional switch comprises field plates extending over access regions of the device. The semiconductor device additionally comprises a secondary circuit that is configured to generate a quasi-reference potential. The quasi-reference potential remains very close to a reference potential that is the lowest potential applied to the device, e.g., GND, during all operational states of the bidirectional switch. The semiconductor device additionally comprises a dedicated quasi-reference potential connection that directly connects the field plate to the quasi-reference potential generating node of the secondary circuit. In this way, the field plates are set at a low potential without any direct connection to the gate of the device. As a result, C_{gd} (gate capacitance) is advantageously reduced as compared to a gate connected field plate version of the device.

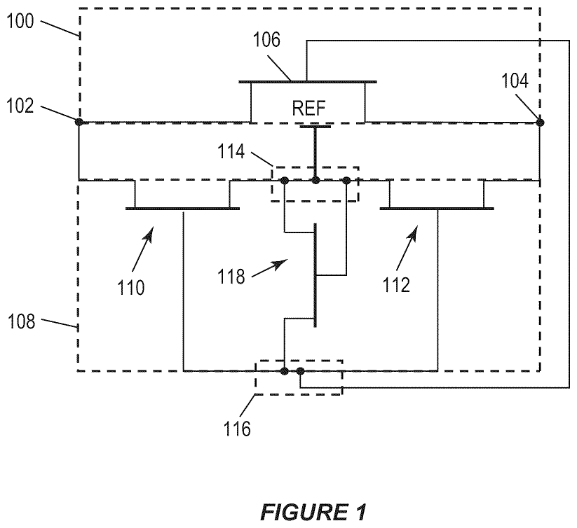

FIG. 1 illustrates a circuit schematic of an embodiment of a semiconductor device that includes a bidirectional switch 100. The bidirectional switch 100 is formed on a semiconductor substrate which is schematically represented by the label ‘SUB’ in FIG. 1. The bidirectional switch 100 comprises first and second input-output terminals 102, 104 and a gate structure 106 configured to control a conduction state of a channel between the first and second input-output terminals 102, 104. The bidirectional switch 100 has an ON state and an OFF state. In the OFF state, the gate structure 106 blocks conduction between the first and second input-output terminals 102, 104 in both current flow directions. In the ON state, the gate structure 106 permits conduction between the first and second input-output terminals 102, 104 in both current flow directions. More specifically, the ON state includes a first direction conduction state in which current flows from the first input-output terminal 102 to the second input-output terminal 104 and a second direction conduction state in which current flows from the second input-output terminal 104 to the first input-output terminal 102. The current flow direction depends on the voltage polarity across the first and second input-output terminals 102, 104.

The semiconductor device additionally comprises a secondary circuit 108 that is wired to the bidirectional switch 100. The secondary circuit 108 comprises first and second switching devices 110, 112. According to an embodiment, the first and second switching devices 110, 112 are each configured as HEMT (high-electron mobility transistor) devices. More generally, the first and second switching devices 110, 112 can be any type of transistor device, such as a MOSFET device. The first and second switching devices 110, 112 are connected in series with one another between the first and second input-output terminals 102, 104 of the bidirectional switch 100. A first terminal of the first switching device 110, e.g., a drain terminal, connects with the first input-output terminal 102 of the bidirectional switch 100. A second terminal of the first switching device, e.g., a source terminal, connects with a first terminal, e.g., a source terminal, of the second switching device at a first node 114 of the secondary circuit 108, which in turn connects with the substrate. A second terminal of the second switching device 112, e.g., a drain terminal, connects with the second input-output terminal 104 of the bidirectional switch 100. Meanwhile, the gate structure 106 of the bidirectional switch 100 and gate terminals of the first and second switching devices 110, 112 are each connected at second node 116 of the secondary circuit 108.

The secondary circuit 108 additionally comprises a rectifier device 118 connected between the first node 114 of the secondary circuit 108 and the second node 116 of the secondary circuit 108. According to the depicted embodiment, the rectifier device 118 is a transistor device that is wired with an electrical short between its gate and source terminals. In this configuration, the device is in voltage blocking mode when a positive drain-source potential is applied and the device is conductive when a negative drain-source potential is applied. That is, the gate-shorted transistor device effectively creates a diode. According to an embodiment, the rectifier device 118 is a HEMT device with a gate-source short. More generally, the rectifier device 118 can be any type of device with one-way conduction characteristics, e.g., a MOSFET with a gate-source short, a p-n junction diode, a Schottky diode, a p-i-n diode, etc.

The operational principle of the secondary circuit 108 is as follows. During an on-state of the bidirectional switch 100 in which a positive potential is applied to the gate of the bidirectional switch 100 relative to a reference potential, e.g., a ground potential, and the bidirectional switch 100 is in either one of the first and second direction conduction states, the first and second switching devices 110, 112 are turned on and the rectifier device 118 is in a blocking state. At this time, the first and second switching devices 110, 112 operate as a resistive voltage divider connected in parallel with the bidirectional switch 100. Assuming the first and second switching devices 110, 112 have substantially equal parameters, the voltage at the first node 114 of the secondary circuit is equal to (V_{D1}+V_{D2})/2≈V_{D1}≈V_{D2}, wherein V_{D1} is the voltage drop across the first switching device 110 and V_{D2} is the voltage drop across the second switching device 112. Accordingly, the first node 114 of the secondary circuit 108 is maintained very close to the reference potential. That is, the potential at the first node 114 only differs from the reference potential by the on-state voltage drop of one of the first and second switching devices 110, 112. During the OFF state of the bidirectional switch 100 in which the gate of the bidirectional switch 100 is biased below the threshold voltage of the device, the rectifier device 118 provides a discharge path between the substrate and the second node 116 of the secondary circuit 116. The potential at the first node 114 is therefore equal to the forward voltage drop of the rectifier device 118. Accordingly, the secondary circuit 108 is configured to generate a quasi-reference potential that is close to the lowest applied potential (typically GND) in both an on-state and an off-state of the bidirectional switch 100 at the first node 114 of the secondary circuit 108. The term ‘quasi-reference’ potential refers to the fact that the potential does not deviate from the reference potential by more than the forward conduction voltage one of the devices within the secondary circuit 108, whether it be one of the first and second switching devices 110, 112 or the rectifier device 118, as the case may be. Thus, the quasi-reference potential is related to the reference potential and deviates from it only by a small amount. In one numerical example, an on state of the bidirectional switch 100, a voltage-drop across the bidirectional switch 100 is close to zero (e.g., V_{DROP}=5A*0.01 Ohm=50 mV-->Vd1=25mV).

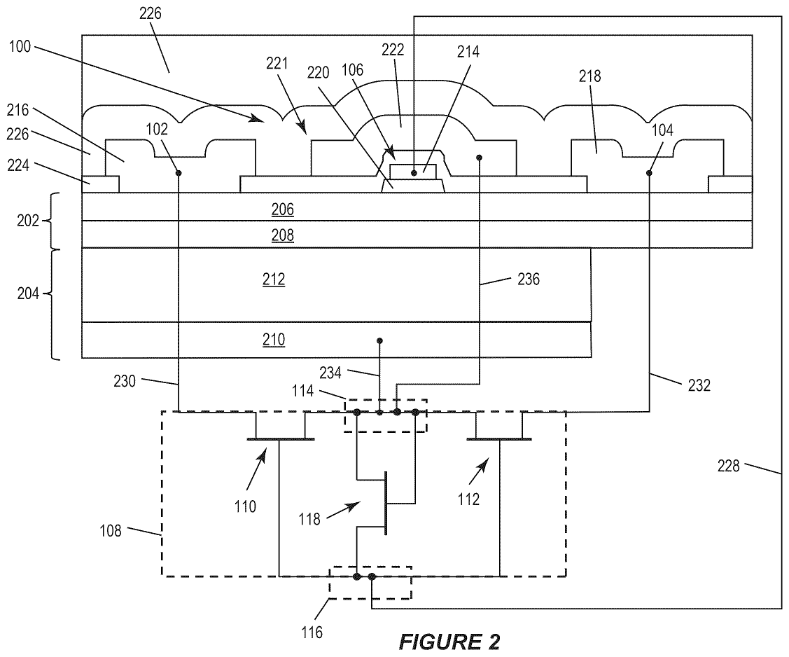

FIG. 2 illustrates a cross-sectional view of an embodiment of the physical implementation of the bidirectional switch 100 in a semiconductor body. The semiconductor body has an active region 202 and a substrate region 204 beneath the active region 202. The active region 202 refers to the layers or regions of the semiconductor body that provide an electrically conductive channel. The substrate region 204 includes various regions of the semiconductor body that do not directly contribute in an electrical sense to the provision of the electrically conductive channel.

According to the depicted embodiment, the bidirectional switch 100 is implemented as a HEMT. In this case, the active region 202 of the semiconductor body comprises a heterojunction interface between a barrier layer 206 of III-V semiconductor material and a channel layer 208 of III-V semiconductor material, wherein the device channel is a two-dimensional charge carrier gas channel that forms in the channel layer 208 near the heterojunction interface. For example, the barrier layer 206 of III-V semiconductor material may include intrinsic or lightly doped aluminum gallium nitride (AlGaN) and the channel layer 208 of III-V semiconductor material may include gallium nitride (GaN). More generally, any combination of type III-V semiconductor materials with different alloying can be used to provide a difference in bandgap. Due to the difference in bandgap between the barrier layer 206 of III-V semiconductor material and the channel layer 208 of III-V semiconductor material, an electrically conductive two-dimensional charge carrier gas channel arises near an interface between the barrier layer 206 and the channel layer 208, due to polarization effects. Below the active region 202, the substrate region 204 of the semiconductor body comprises a base substrate 210 and a lattice transition region 212. The base substrate 210 may include or be formed from group IV or group III-V semiconductor materials. For example, according to one embodiment, the base substrate 210 may be a silicon wafer or silicon-based wafer. The lattice transition region 212 may include multiple semiconductor nitride layers (e.g., AlGaN layers) with a varying alloy concentration and may include other layers including electrically insulating layers. Other layers or regions may also be provided below the active region 202, such as nucleation layers and back-barrier regions.

According to the depicted embodiment, the bidirectional switch 100 is implemented as an HEMT. In this case, the active region 202 of the semiconductor body comprises a heterojunction interface between a barrier layer 206 of III-V semiconductor material and a channel layer 208 of III-V semiconductor material, wherein the device channel is a two-dimensional charge carrier gas channel that forms in the channel layer 208 near the heterojunction interface. For example, the barrier layer 206 of III-V semiconductor material may include intrinsic or lightly doped aluminum gallium nitride (AlGaN) and the channel layer 208 of III-V semiconductor material may include gallium nitride (GaN). More generally, any combination of type III-V semiconductor materials with different alloying can be used to provide a difference in bandgap. Due to the difference in bandgap between the barrier layer 206 of III-V semiconductor material and the channel layer 208 of III-V semiconductor material, an electrically conductive two-dimensional charge carrier gas channel arises near an interface between the barrier layer 206 and the channel layer 208, due to polarization effects. Below the active region 202, the substrate region 204 of the semiconductor body comprises a base substrate 210 and a lattice transition region 212. The base substrate 210 may include or be formed from group IV or group III-V semiconductor materials. For example, according to one embodiment, the base substrate 210 may be a silicon wafer or silicon-based wafer. The lattice transition region 212 may include multiple semiconductor nitride layers (e.g., AlGaN layers) with a varying alloy concentration and may include other layers including electrically insulating layers. Other layers or regions may also be provided below the active region 202, such as nucleation layers and back-barrier regions.

As shown, the gate structure 106 of the bidirectional switch 100 comprises an electrically conductive gate electrode 214 that is configured to control the two-dimensional charge carrier gas channel. The first and second input-output terminals 102, 104 of the bidirectional switch 100 respectively comprise a first input-output terminal electrode 216 and second input-output terminal electrode 218 that are formed on the upper surface of the semiconductor body and in low-ohmic contact with the two-dimensional charge carrier gas channel. Each of the gate electrode 214, the first input-output terminal electrode 216, and the second input-output terminal electrodes 218 may be formed in a lower-level interconnect layer that is formed before the upper-level metallization layers (not shown in FIG. 2). That is, the electrodes of the device may be formed in a so-called front-end interconnect layer. This lower-level interconnect layer may comprise an electrical conductor such as a metal, e.g., aluminum, titanium, copper, nickel, tungsten, alloys thereof, etc., or a doped semiconductor, e.g., highly doped monocrystalline or polycrystalline semiconductors. Each of the gate electrode 214, the first input-output terminal electrode 216, and the second input-output terminal electrode 218 may be connected to externally accessible bond pads, thereby forming externally accessible terminals of the device. The gate structure 106 provides on/off control of the high-electron mobility transistor by controlling an electric field that depletes or repopulates the two-dimensional charge carrier gas channel underneath the gate electrode 214, thereby controlling a conductive connection between the first input-output terminal to the second input-output terminal. As shown, the gate structure 106 may additionally comprise a first region 220 of doped type III-V semiconductor material in between the gate electrode 214 and an upper surface of the semiconductor body. According to an embodiment, the first region 220 of doped type III-V semiconductor material comprises p-type GaN or alloys thereof (e.g., p-type AlGaN). Parameters of the first region 220 of doped type III-V semiconductor material, e.g., thickness, dopant concentration, etc., may be tailored to create an electric field that locally depletes the two-dimensional charge carrier gas channel underneath the gate structure 106 at zero-gate-source bias, thereby providing a normally-off device configuration.

In other embodiments wherein the bidirectional switch 100 is not implemented as a HEMT, the active region 202 may include group IV semiconductor materials such as Silicon (Si), Silicon carbide (SiC), Silicon germanium (SiGe), etc. The semiconductor materials may be doped to form active device regions, e.g., source, drain, collector, emitter, etc., which provide a controllable electrically conductive channel in a known manner.

The bidirectional switch 100 additionally comprises a field plate structure 221 configured to influence electric field distribution between the gate structure 106 and each of the first and second input-output terminals 102, 104. The field plate structure 221 comprises a field plate 222 that extends over access regions of the bidirectional switch 100 on either side of the gate structure 106. As shown, the field plate 222 may be a single continuous structure that is vertically above the gate electrode 214 and extends past either side of the gate electrode 214. The field plate 222 mitigates peak electric fields within the device, which leads to improved behavior including higher breakdown voltage. The field plate 222 may be formed by an electrical conductor such as a metal, e.g., aluminum, titanium, copper, nickel, tungsten, alloys thereof, etc., or a doped semiconductor, e.g., highly doped monocrystalline or polycrystalline semiconductors, and may be formed in the same lower-level interconnect layer as the gate electrode 214 and the first and second input-output terminal electrodes 216, 218.

The semiconductor device additionally comprises electrically insulating layers formed on the upper surface of the semiconductor body. In the depicted embodiment, these electrically insulating layers include a passivation layer 224 formed directly on the upper surface of the semiconductor body and interlayer dielectric layers 226 disposed thereon, each of which may be formed from an electrically insulating material such as SiO₂ (silicon dioxide), Si₃N₄ (silicon nitride), SiO_{X}N_{Y} (silicon oxynitride), etc. As shown, the passivation layer 224 may be structured with openings and the first and second input-output terminal electrodes 216, 218 \may be deposited within these openings. The field plate 222 is deposited on the passivation layer over the gate structure 106 and the interlayer dielectric layers cover and encapsulates the field plate 222 and the first and second input-output terminal electrodes 216, 218.

The semiconductor device may additionally comprise one or more upper-level metallization layers (not shown in FIG. 2) formed over the above-described electrically insulating layers. These upper-level metallization layers may be so-called back end of the line metallization layers that are used to wire the various devices formed in the semiconductor body and provide externally accessibly bond pads. These upper-level metallization layers may be structured into tracks and may be formed of a conductive metal, e.g., copper, aluminum, etc., and alloys thereof.

The bidirectional switch 100 is electrically connected with the secondary circuit 108 as described above, which is again schematically represented in FIG. 2. The various elements of the secondary circuit 108 may be incorporated into a different region of the semiconductor body as the cross-sectional view of FIG. 2 which shows the bidirectional switch 100. The electrical connections between the bidirectional switch 100 and the secondary circuit 108 comprise a gate connection 228 that electrically connects the gate structure 106 with the second node 116 of the secondary circuit 108, a first input-output terminal connection 230 that electrically connects the first input-output terminal 102 of the bidirectional switch 100 with the first terminal of the first switching device 110, and a second input-output terminal connection 232 that electrically connects the second input-output terminal 104 of the bidirectional switch 100 with the second terminal of the second switching device 112. Each of these electrical connections may be effectuated at least partially by the upper-level metallization layers, as described above. Additionally, there is a substrate connection 234 between the first node 114 of the secondary circuit 108 and the substrate region 204 of the semiconductor body. The substrate connection 234 may be provided by a conductive via that extends through the active region 202 and is outside of the cross-sectional view of FIG. 2.

The semiconductor device additionally comprises a quasi-reference potential connection 236 that directly connects the field plate 222 of the bidirectional circuit to the first node 114 of the secondary circuit 108. This quasi-reference potential connection 236 is schematically represented in FIG. 2. The quasi-reference potential connection 236 is a dedicated connection between the field plate 222 of the bidirectional switch 100 and the first node 114 of the secondary circuit 108 that is physically separate from the gate connection 228. The field plate 222 is vertically spaced apart from the gate electrode 214 and electrically insulated from the gate electrode 214 by electrically insulating material. In this way, the field plate 222 is advantageously set at the quasi-reference potential, which provides the necessary low potential for electric field shaping during both conduction directions of the bidirectional switch 100, while also being physically disconnected from the gate electrode 214 and not contributing to the gate—drain (or gate—outside electrode) capacitance of the device.

Described below are various layouts of a semiconductor device comprising the bidirectional switch 100, the secondary circuit 108 and the quasi-reference potential connection 236 that directly connects the field plate 222 to the first node 114 of the secondary circuit 108.

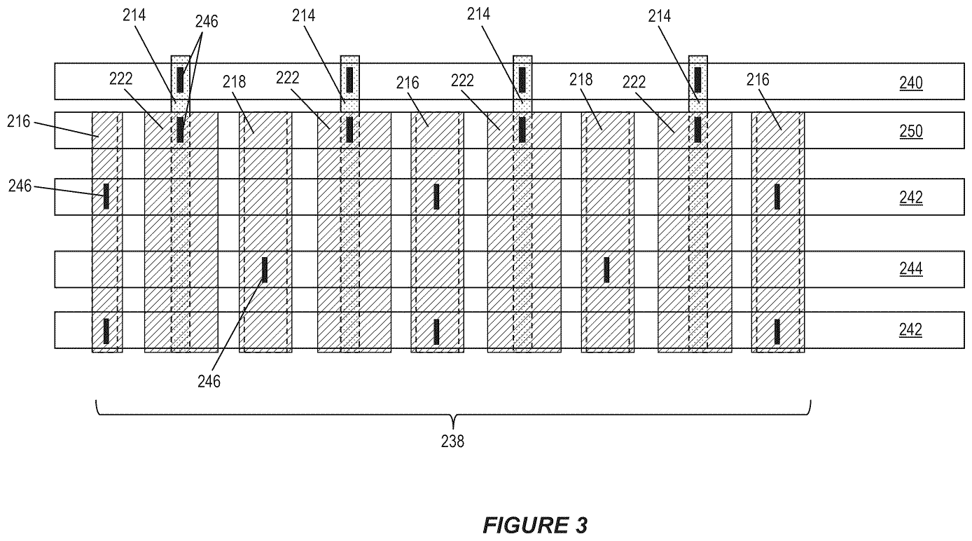

Referring to FIG. 3, a plan-view layout of an active area 238 of the semiconductor body that comprises the bidirectional switch 100 is shown. In this embodiment, the bidirectional switch 100 comprises a plurality of the gate electrodes 214, a plurality of the field plates 222 overlapping with the gate electrodes 214, a plurality of the first input-output terminal electrodes 216, and a plurality of the second input-output terminal electrodes 218. A group comprising one of gate electrodes 214, one of the field plates 222, and a pair of the first and second input-output terminal electrodes 216, 218 forms one device cell, wherein these device cells are connected in parallel with one another to form a single functional device. In this layout, the gate electrodes 214, the field plates 222, and the first and second input-output terminal electrodes 216, 218 are arranged as elongated columns within the active area 238 of the semiconductor body. That is, the gate electrodes 214, the field plates 222, and the first and second input-output terminal electrodes 216, 218 are each formed in a stripe pattern that extends perpendicular to the current flow direction of the bidirectional switch 100.

The gate connection 228 (described with reference to FIG. 2) that electrically connects the gate structure 106 with the second node 116 of the secondary circuit 108 comprises a gate bus 240 that is electrically connected with each of the gate electrodes 214. The first input-output electrode connection 230 (described with reference to FIG. 2) comprises a plurality of first input-output electrode buses 242 electrically connected with each of the first input-output terminal electrodes 216. The second input-output electrode connection 232 (described with reference to FIG. 2) comprises a plurality of second input-output electrode buses 244 (only one seen in the figure) that are electrically connected with each of the second input-output terminal electrodes 218. Each of the gate bus 240, the first input-output electrode buses 242, and the second input-output electrode buses 244 are formed in an upper-level metallization layer and extend across the active area 238 transversely to the gate electrodes 214 and the field plates 222. The electrical connections between the gate bus 240, the first input-output electrode buses 242, and the second input-output electrode buses 244 are each effectuated by vertical through-vias 246 that extend through electrically insulating layers interposed between the two interconnect levels. According to an embodiment, each of the gate bus 240, the first input-output electrode buses 242, and the second input-output electrode buses 244 are formed in the same upper-level metallization layer. More particularly, each of the gate bus 240, the first input-output electrode buses 242, and the second input-output electrode buses 244 may be formed in a first upper-level metallization layer that is immediately above the dielectric material encapsulating the field plates 222.

The quasi-reference potential connection 236 (described with reference to FIG. 2) that directly connects the field plate 222 to the first node 114 of the secondary circuit 108 comprises a first elongated span of metal 250 that is electrically connected with each of the field plates 222. The first elongated span of metal 250 extends across the active area 238 transversely to the gate electrodes 214 and the field plates 222.

According to the embodiment of FIG. 3, the first elongated span of metal 250 is formed in an upper-level metallization layer. More particularly, the first elongated span of metal 250 from the quasi-reference potential connection 236 may be formed in the same metallization layer as the gate bus 240, the first input-output electrode buses 242, and the second input-output electrode buses 244. More particularly, each of the gate bus 240, the first input-output electrode buses 242, the second input-output electrode buses 244 and the first elongated span of metal 250 may be formed in a first upper-level metallization layer that is immediately above the dielectric material encapsulating the field plates 222.

According to the embodiment of FIG. 3, each of the gate electrodes 214 extend past ends of field plates 222 into a non-overlapping area, and the gate bus 240 extends directly over the gate electrodes 214 and is electrically connected to each of the gate electrodes 214 by vertical through-vias 246 in the non-overlapping area. In this way, the connection to the gate bus 240 and the connection to the first elongated span of metal 250 may be effectuated without interference.

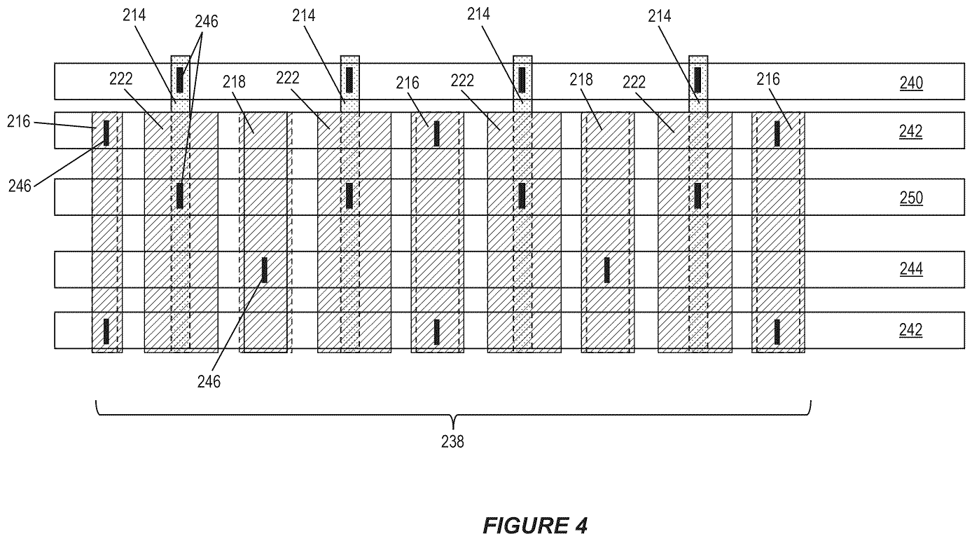

Referring to FIG. 4, a plan-view layout of an active area 238 of the semiconductor body that comprises the bidirectional switch 100 is shown, according to another embodiment. In this embodiment, the first elongated span of metal 250 from the quasi-reference potential connection 236 (described with reference to FIG. 2) is arranged vertically in between one of the first input-output electrode buses 242 and one of the second input-output electrode buses 244. That is, from the perspective of FIG. 4, the first elongated span of metal 250 is routed along a plane that is below that of one of the first input-output electrode buses 242 and above that of one of the second input-output electrode buses 244.

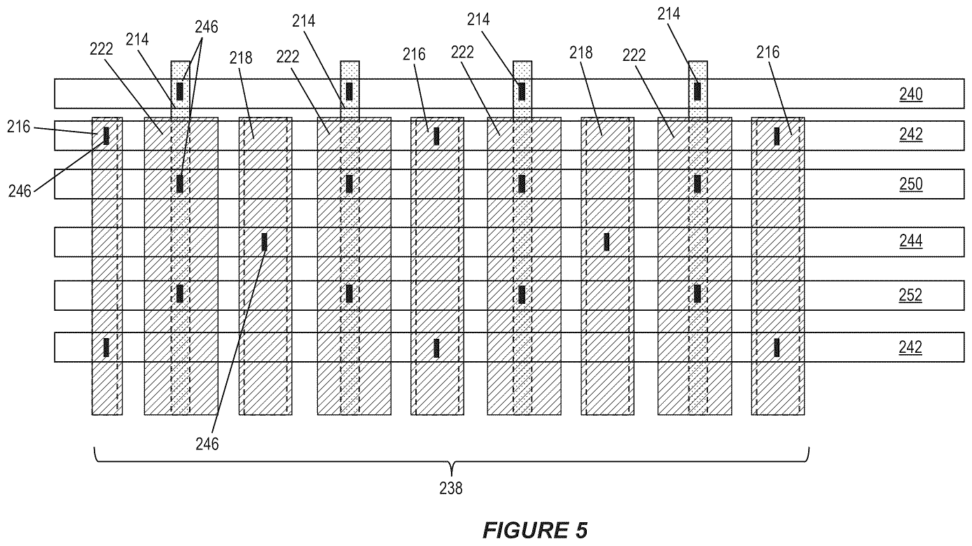

Referring to FIG. 5, a plan-view layout of an active area 238 of the semiconductor body that comprises the bidirectional switch 100 is shown, according to another embodiment. In this embodiment, the quasi-reference potential connection 236 (described with reference to FIG. 2) comprises a second elongated span of metal 252 that extends across the active area 238 transversely to the gate electrodes 214 and the field plates 222. The second elongated span of metal 252 is formed in the same metallization level as the other connection busses and is arranged vertically in between one of the first input-output electrode buses 242 one of the second input-output electrode buses 244. This layout arrangement may be preferable to optimize the propagation delay between the secondary circuit 108 and the field plates 222. In principle, any number of separate connection busses of the quasi-reference potential connection 236, e.g., three, four, five, etc., may be used to obtain a greater degree of parallelization.

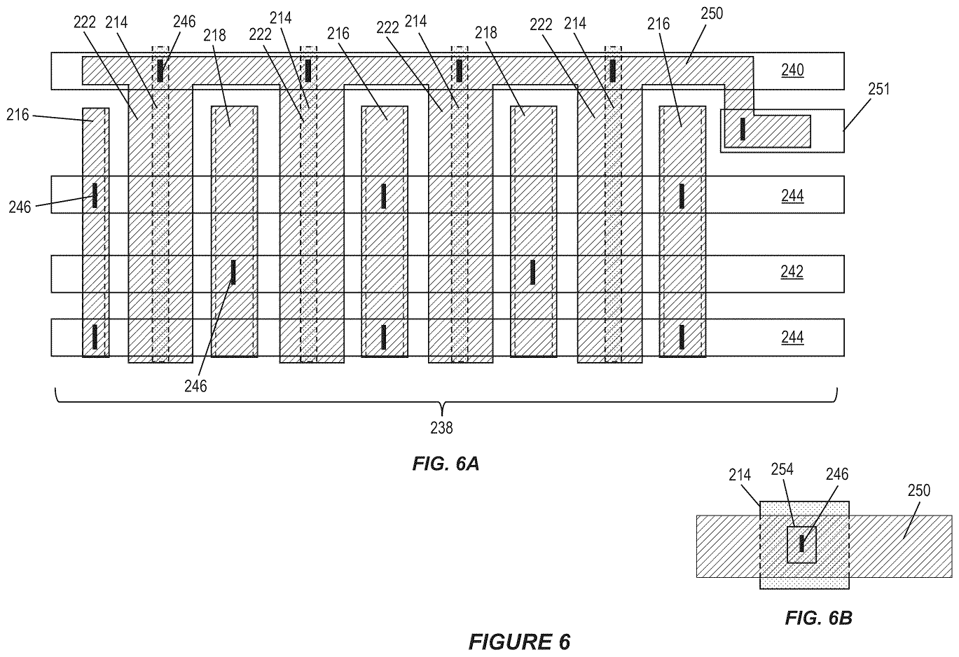

Referring to FIG. 6, a plan-view layout of an active area 238 of the semiconductor body that comprises the bidirectional switch 100 is shown, according to an embodiment. In the embodiment of FIG. 6, the quasi-reference potential connection 236 (described with reference to FIG. 2) comprises a first elongated span of metal 250 that is formed in a lower-level metallization that is underneath the upper-level metallization layer that the gate bus 240, the first input-output electrode buses 242, the second input-output electrode buses 244 are formed in. In this case, the first elongated span of metal 250 directly connects and merges with each of the field plates 222. That is, the quasi-reference potential connection 236 comprises a continuous metal structure that forms the field plates 222 and connects each of the field plates 222 together. As shown, this first elongated span of metal 250 may be connected outside of the active area 238 to a connecting span 251 of metal that is formed in the upper-level metallization layer

As shown in FIG. 6A, the gate bus 240 directly overlaps with the first elongated span of metal 250 in the active area 238. That is, the gate bus 240 is routed directly above the quasi-reference potential connection 236 that comprises the span of metal 250, due to the provision of these connections on different metallization levels. In this way, area efficiency may be improved.

As shown in FIG. 6B, the first elongated span of metal 250 in the active area 238 comprises openings 254. The gate bus 240 is electrically connected with each of the gate electrodes 214 by vertical through-vias 246 that extend through the openings 254. There is a clearance between the vertical through-vias 246 and inner edge sides of the openings 254, which may be filled with an electrical insulator, so that the gate bus 240 is electrically isolated and independent from the first elongated span of metal 250. In this way, the direct overlap between the gate bus 240 and the first elongated span of metal 250 is possible.

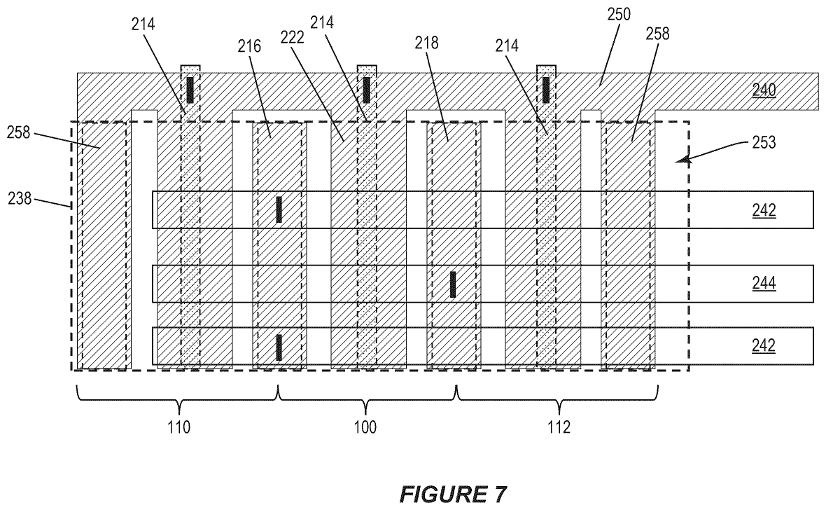

Referring to FIG. 7, a plan-view layout of an active area 238 of the semiconductor body that comprises the bidirectional switch 100 is shown, according to an embodiment. In the embodiment of FIG. 7, the active area 238 additionally comprises the first and second switching devices 110, 112 of the secondary circuit 108 formed adjacent to the bidirectional switch 100. In this case, the first and second switching devices 110, 112 each comprise elongated gate electrodes 214 and outer terminal electrodes 258 that are arranged as elongated columns within the active area 238 of the semiconductor body. In more detail, the first switching device 110 comprises an outer terminal electrode 258 and a gate electrode 214 arranged between the outer terminal electrode 258 and the first input-output terminal electrode 216. In this arrangement, the first input-output terminal electrode 216 forms the first terminal of the first switching device 110 and the outer terminal electrode 258 forms the second terminal of the first switching device 110. The second switching device 112 comprises an outer terminal electrode 258 and a gate electrode 214 arranged between the outer terminal electrode 258 and the second input-output terminal electrode 218. In this arrangement, the second input-output terminal electrode 218 forms the second terminal of the first switching device 110 and the outer terminal electrode 258 forms the first terminal of the first switching device 110.

Similar to the previously discussed embodiment, in this embodiment the quasi-reference potential connection 236 (described with reference to FIG. 2) comprises a first elongated span of metal 250 that is formed in a lower-level metallization that is underneath the upper-level metallization layer that the gate bus 240. In this case, the elongated span of metal 250 forms a direct connection with the outer terminal electrodes 258 associated with each of the first and second switching devices 110, 112, thereby completing the electrical connection with the first node 114 (described with reference to FIG. 2) of the secondary circuit 108.

FIG. 7 illustrates damage implanted region 253 formed around the active area 238. The damage implanted region 253 selectively deactivates the gate structures of the devices outside of the active area 238, thereby preventing an electrical short between the third and fourth outer terminal electrodes 258. The damage implanted region 253 can be created by implanting any one or combination of impurity atoms into first regions 220 of doped type III-V semiconductor material (e.g., as seen in FIG. 2) and/or the barrier layer 206 and the channel layer 208 that are in between the gate electrodes 214 and an upper surface of the semiconductor body, e.g., the regions of p-type GaN in between each of the gate electrodes 214 and the semiconductor body. These impurity atoms modify the gate structures to create a permanently non-conductive channel immediately underneath them. The damage implanted region 253 may be incorporated into any of the previously described embodiments with reference to FIGS. 3-6 to similar effect.

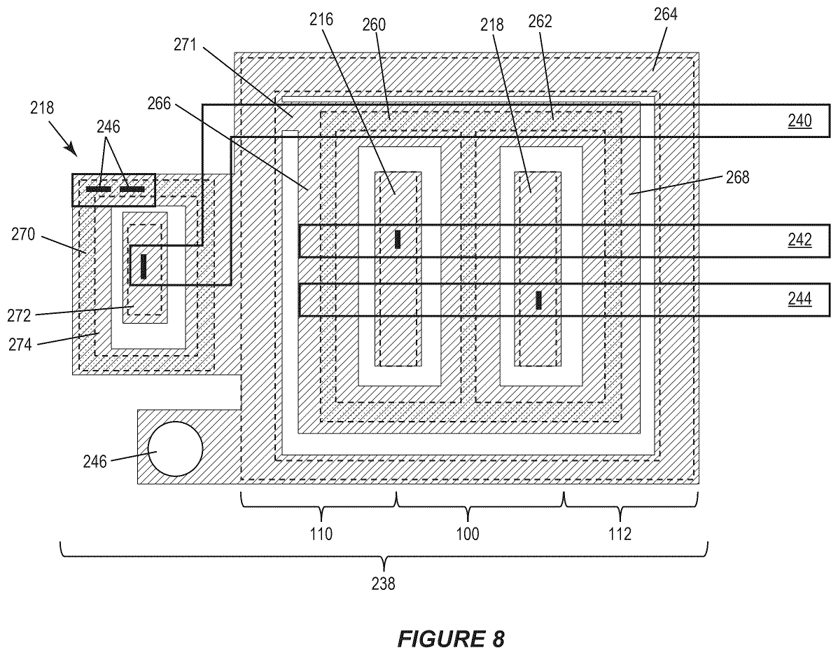

Referring to FIG. 8, a plan-view layout of an active area 238 of the semiconductor body that comprises the bidirectional switch 100 is shown, according to an embodiment. In the previously described embodiment of FIG. 7, the damage implantation may have detrimental effects on the gate structures between the active area 238 and the damage implanted region 253. The embodiment of FIG. 8 avoids the need to provide damage implantation within the gate structures of the devices. In this case, the devices are created by an enclosed ring-based layout. In more detail, the semiconductor device comprises first and second enclosed gate electrode rings 260, 262 that directly adjoin one another. A first input-output terminal electrode 216 is arranged within the first enclosed gate electrode ring 260. A second input-output terminal electrode 218 is arranged within the second enclosed gate electrode ring. The gate electrode 214 of the bidirectional switch 100 (as seen in FIG. 2) is formed by a central span of the first and second enclosed gate electrode rings 260, 262 in between the first and second input-output terminal electrodes 216, 220. The semiconductor device additionally comprises an enclosed outer electrode ring 264 that surrounds the first and second enclosed gate electrode rings 260, 262 and is in ohmic contact with the two-dimensional charge carrier gas channel. The enclosed outer electrode ring 264 forms the first terminal of the first switching device 110 and the second terminal of the second switching deice 112 which are connected to the node 114, while the first and second enclosed gate electrode rings 260, 262 create the gate structure of the first and second switching devices 110, 112, respectively.

In the embodiment of FIG. 8, the semiconductor device comprises first and second enclosed field plate rings 266, 268 that are formed in the lower-level metallization and overlap with the first and second enclosed gate electrode rings 260, 262. These first and second enclosed field plate rings 266, 268 form the field plate structure 221 of the bidirectional switch 100 (as seen in FIG. 2). Specifically, the field plate 222 of the bidirectional switch 100 is formed by a central span of the first and second enclosed field plate rings 266, 268 that is above the central span of the first and second enclosed gate electrode rings 260, 262 in between the first and second input-output terminal electrodes 216, 218.

In the embodiment of FIG. 8, the quasi-reference potential connection 236 comprises a connection between the first and second enclosed field plate rings 266, 268 and the enclosed outer electrode ring 264. In particular, the quasi-reference potential connection 236 comprises a discrete span 271 of the lower-level metallization that extends across a gap between the first and second enclosed field plate rings 266, 268 and the enclosed outer electrode ring 264. This connects the field plate structure 221 of the bidirectional switch 100 with the enclosed outer electrode ring 264, which in turn is connected with the other elements of the secondary circuit 108 to form the first node 114 of the secondary circuit 108 (as seen in FIG. 2).

FIG. 8 additionally shows an exemplary layout of the rectifier device 118 from the secondary circuit 108 and the substrate connection 234 (as seen in FIG. 2), thus depicting the complete secondary circuit 108 and associated connections. As shown in FIG. 8, the rectifier device 118 may be realized by third enclosed gate electrode ring 270 disposed outside of the enclosed outer electrode ring 264 and a source terminal electrode column 272 arranged within third enclosed gate electrode ring 270. The source terminal electrode column 272 is electrically connected with the gate bus 240, thereby completing the gate connection 228 (as seen in FIG. 2). The third enclosed gate electrode ring 270 is covered by an enclosed conductive ring 274 formed in the lower-level metallization layer that is connected with the enclosed outer electrode ring 264, thereby forming the drain terminal of the rectifier device 118. The gate-source short is effectuated by vertical through-vias 246 that connect the third enclosed gate electrode ring 270 with the enclosed conductive ring 274. The substrate connection is realized by an electrically conductive through-via 246 that is connected with the first node 114 of the secondary circuit 108 via the lower-level of metallization. This conductive through-via 246 may extend through the active region 202 and form a direct low-ohmic contact with the substrate region 204, e.g., as seen in FIG. 2. The through-via 246 can comprise electrically conductive materials such as aluminum, titanium, copper, nickel, tungsten, alloys thereof, etc.

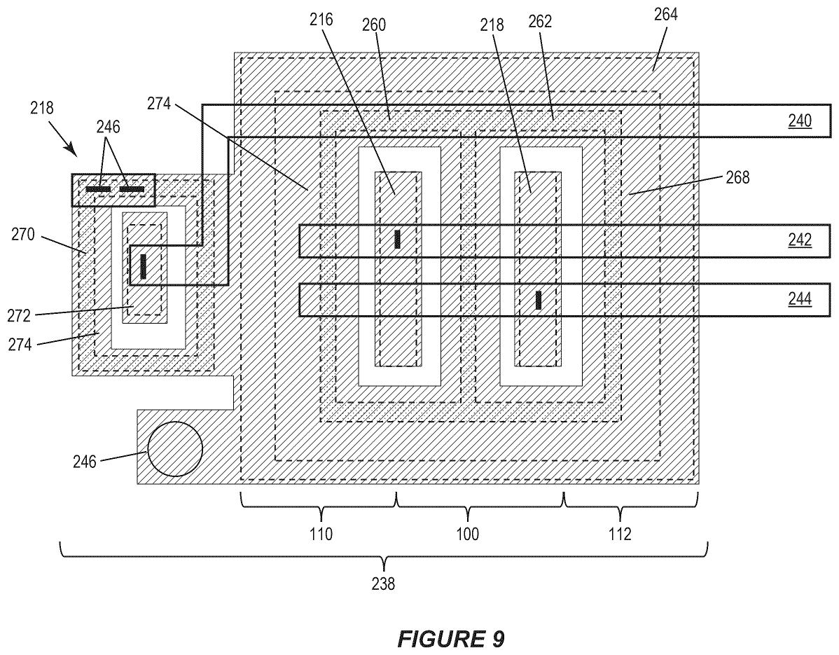

Referring to FIG. 9, a plan-view layout of an active area 238 of the semiconductor body that comprises the bidirectional switch 100 is shown, according to an embodiment. The layout of FIG. 9 is similar to that of FIG. 8, except that a continuous region 274 of lower-level metallization is disposed inside of the enclosed outer electrode ring 264 that extends over the first and second enclosed gate electrode rings 260, 262. The field plate structure 221 of the bidirectional switch 100 is formed by a central span of the continuous region 274 of lower-level metallization that is above the central span of the first and second enclosed gate electrode rings 260, 262 in between the first and second input-output terminal electrodes 216, 220. The quasi-reference potential connection 236 (as seen in FIG. 2) comprises the continuous region 274 of lower-level metallization that connects the field plate structure 221 of the bidirectional switch 100 with the enclosed outer electrode ring 264. This layout may be preferred to lower the resistance of the quasi-reference potential connection 236.

Although the present disclosure is not so limited, the following numbered examples demonstrate one or more aspects of the disclosure.

Example 1. A semiconductor device, comprising: a semiconductor body comprising an active region and a substrate region beneath the active region; a bidirectional switch comprising: first and second input-output terminals; a gate structure configured to control a conduction state of a channel within the active region between the first and second input-output terminals, the gate structure comprising one or more gate electrodes; and a field plate structure configured to influence electric field distribution between the gate structure and each of the first and second input-output terminals, the field plate structure comprising a field plate for each of the one or more gate electrodes that extends over access regions on either side of the one or more gate electrodes; a secondary circuit configured to generate a quasi-reference potential in both an on-state and an off-state of the bidirectional switch at a first node of the secondary circuit; and a quasi-reference potential connection that directly connects the field plate to the first node.

Example 2. The semiconductor device of example 1, further comprising a gate connection that electrically connects the gate structure with a second node of the secondary circuit, and wherein the quasi-reference potential connection is physically separate from the gate connection.

Example 3. The semiconductor device of example 2, wherein the first node is electrically connected to the substrate region, and wherein the secondary circuit comprises a rectifier device connected between the first node and the second node.

Example 4. The semiconductor device of example 3, wherein the rectifier device is a transistor device that is wired with an electrical short between gate and source terminals of the transistor device.

Example 5. The semiconductor device of example 3, wherein the active region of the semiconductor body comprises a heterojunction interface between a barrier layer of III-V semiconductor material and a channel layer of III-V semiconductor material, wherein the channel is a two-dimensional charge carrier gas channel that forms in the channel layer near the heterojunction interface, wherein the substrate region comprises a base substrate of IV semiconductor material, and wherein the first node is electrically connected to the substrate region by a conductive via that extends through the active region.

Example 6. The semiconductor device of example 3, wherein the secondary circuit further comprises first and second switching devices, wherein the first and second switching devices are connected in series between the first and second input-output terminals, wherein a second terminal of the first switching device connects with a first terminal of the second switching device at the first node of the secondary circuit, and wherein the gate structure of the bidirectional switch and gate terminals of the first and second switching devices each connect to one another at the second node of the secondary circuit.

Example 7. The semiconductor device of example 1, wherein each of the gate electrodes and the field plates are arranged as elongated columns within an active area of the semiconductor body, and wherein the quasi-reference potential connection comprises a first elongated span of metal that extends across the active area transversely to the gate electrodes and the field plates.

Example 8. The semiconductor device of example 7, wherein the semiconductor device further comprises a gate bus, a first input-output electrode bus, and a second input-output electrode bus, wherein each of the gate bus and the first and second input-output electrode buses are formed in an upper-level metallization layer and extend across the active area transversely to the gate electrodes and the field plates.

Example 9. The semiconductor device of example 8, wherein each of the gate bus, the first and second input-output electrode buses, and the first elongated span of metal are formed in a first upper-level metallization layer that is immediately above the field plate structure.

Example 10. The semiconductor device of example 9, wherein each of the gate electrodes extend past ends of field plates into a non-overlapping area, and wherein the gate bus extends directly over the gate electrodes and is electrically connected to each of the gate electrodes by vertical through-vias in the non-overlapping area.

Example 11. The semiconductor device of example 8, wherein the first elongated span of metal is arranged vertically in between the first input-output electrode bus and the second input-output electrode bus.

Example 12. The semiconductor device of example 11, wherein the semiconductor device comprises a plurality of the first input-output electrode buses, and a plurality the second input-output electrode buses, wherein the quasi-reference potential connection comprises a second elongated span of metal that extends across the active area transversely to the gate electrodes and the field plates, and wherein the second elongated span of metal is arranged vertically in between a further one of the first input-output electrode buses and a further one of the second input-output electrode buses.

Example 13. The semiconductor device of example 8, wherein the first elongated span of metal is formed in a lower-level metallization that is underneath the upper-level metallization layer, and wherein the first elongated span of metal directly connects and merges with each of the field plates.

Example 14. The semiconductor device of example 13, wherein the gate bus directly overlaps with the first elongated span of metal in the active area, wherein the first elongated span of metal comprises a plurality of openings, and wherein the gate bus is electrically connected with each of the gate electrodes by vertical through-vias that extend through the openings.

Example 15. The semiconductor device of example 8, wherein the secondary circuit comprises first and second switching devices connected in parallel with the bidirectional switch, wherein the first and second switching devices each comprise elongated gate electrodes and outer terminal electrodes that are arranged as elongated columns within the active area of the semiconductor body, wherein the first elongated span of metal is formed in a lower-level metallization that is underneath the upper-level metallization layer, and wherein the first elongated span of metal directly connects and merges with each of the field plates and the outer terminal electrodes of the first and second switching devices.

Example 16. The semiconductor device of example 1, wherein the semiconductor device comprises first and second enclosed gate electrode rings immediately adjacent to one another and an enclosed outer electrode ring that at least partially surrounds the first and second enclosed gate electrode rings, wherein the first input-output terminal comprises a first input-output terminal electrode that is arranged within the first enclosed gate electrode ring, wherein the second input-output terminal comprises a second input-output terminal electrode that is arranged within the second enclosed gate electrode ring, and wherein the one or more gate electrodes of the gate structure comprise a central span of the first and second enclosed gate electrode rings in between the first and second input-output terminal electrodes.

Example 17. The semiconductor device of example 16, further comprising an enclosed outer electrode ring that surrounds the first and second enclosed gate electrode rings, wherein the secondary circuit comprises first and second switching devices connected in series between the first and second input-output terminals of the bidirectional switch, wherein the enclosed outer electrode ring forms a first terminal of the first switching device that is connected with the first input-output terminal of the bidirectional switch and a second terminal of the second switching device that is connected with the second input-output terminal of the bidirectional switch, and wherein the first and second enclosed gate electrode rings form gate electrodes of the first and second switching devices, respectively.

Example 18. The semiconductor device of example 17, wherein the semiconductor device comprises first and second enclosed field plate rings that are formed in a lower-level metallization and overlap with the first and second enclosed gate electrode rings, respectively, wherein the first and second enclosed field plate rings form the field plate structure of the bidirectional switch, and wherein the quasi-reference potential connection comprises a discrete span of the lower-level metallization that extends across a gap between the first and second enclosed field plate rings and the enclosed outer electrode ring.

Example 19. The semiconductor device of example 17, wherein the semiconductor device comprises a continuous region of lower-level metallization that is disposed inside of the enclosed outer electrode ring extends over the first and second enclosed gate electrode rings, wherein the continuous region of lower-level metallization forms the field plate structure of the bidirectional switch, and wherein the quasi-reference potential connection comprises the continuous region of lower-level metallization.

Example 20. The semiconductor device of example 17, wherein the secondary circuit comprises a rectifier device connected between the first node and a second node of the secondary circuit, wherein the rectifier device comprises a third enclosed gate electrode ring disposed outside of the enclosed outer electrode ring, a source terminal electrode column arranged within the third enclosed gate electrode ring, and an enclosed conductive ring formed in a lower-level metallization layer, wherein the enclosed conductive ring is directly connected with the third enclosed gate electrode ring by vertical through-vias.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

Spatially relative terms, such as “beneath,” “below,” “lower,” “above,” “upper”, “under” and the like, are used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is to be understood that the features of the various embodiments described herein may be combined with each other, unless specifically noted otherwise. Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a semiconductor body comprising an active region and a substrate region beneath the active region;
a bidirectional switch comprising:
first and second input-output terminals;
a gate structure configured to control a conduction state of a channel within the active region between the first and second input-output terminals, the gate structure comprising one or more gate electrodes; and
a field plate structure configured to influence electric field distribution between the gate structure and each of the first and second input-output terminals, the field plate structure comprising a field plate for each of the one or more gate electrodes that extends over access regions on either side of the one or more gate electrodes;
a secondary circuit configured to generate a quasi-reference potential in both an on-state and an off-state of the bidirectional switch at a first node of the secondary circuit; and
a quasi-reference potential connection that directly connects the field plate to the first node.

2. The semiconductor device of claim 1, further comprising a gate connection that electrically connects the gate structure with a second node of the secondary circuit, and wherein the quasi-reference potential connection is physically separate from the gate connection.

3. The semiconductor device of claim 2, wherein the first node is electrically connected to the substrate region, and wherein the secondary circuit comprises a rectifier device connected between the first node and the second node.

4. The semiconductor device of claim 3, wherein the rectifier device is a transistor device that is wired with an electrical short between gate and source terminals of the transistor device.

5. The semiconductor device of claim 3, wherein the active region of the semiconductor body comprises a heterojunction interface between a barrier layer of III-V semiconductor material and a channel layer of III-V semiconductor material, wherein the channel is a two-dimensional charge carrier gas channel that forms in the channel layer near the heterojunction interface, wherein the substrate region comprises a base substrate of IV semiconductor material, and wherein the first node is electrically connected to the substrate region by a conductive via that extends through the active region.

6. The semiconductor device of claim 3, wherein the secondary circuit further comprises first and second switching devices, wherein the first and second switching devices are connected in series between the first and second input-output terminals, wherein a second terminal of the first switching device connects with a first terminal of the second switching device at the first node of the secondary circuit, and wherein the gate structure of the bidirectional switch and gate terminals of the first and second switching devices each connect to one another at the second node of the secondary circuit.

7. The semiconductor device of claim 1, wherein each of the gate electrodes and the field plates are arranged as elongated columns within an active area of the semiconductor body, and wherein the quasi-reference potential connection comprises a first elongated span of metal that extends across the active area transversely to the gate electrodes and the field plates.

8. The semiconductor device of claim 7, wherein the semiconductor device further comprises a gate bus, a first input-output electrode bus, and a second input-output electrode bus, wherein each of the gate bus and the first and second input-output electrode buses are formed in an upper-level metallization layer and extend across the active area transversely to the gate electrodes and the field plates.

9. The semiconductor device of claim 8, wherein each of the gate bus, the first and second input-output electrode buses, and the first elongated span of metal are formed in a first upper-level metallization layer that is immediately above the field plate structure.

10. The semiconductor device of claim 9, wherein each of the gate electrodes extend past ends of field plates into a non-overlapping area, and wherein the gate bus extends directly over the gate electrodes and is electrically connected to each of the gate electrodes by vertical through-vias in the non-overlapping area.

11. The semiconductor device of claim 8, wherein the first elongated span of metal is arranged vertically in between the first input-output electrode bus and the second input-output electrode bus.

12. The semiconductor device of claim 11, wherein the semiconductor device comprises a plurality of the first input-output electrode buses, and a plurality the second input-output electrode buses, wherein the quasi-reference potential connection comprises a second elongated span of metal that extends across the active area transversely to the gate electrodes and the field plates, and wherein the second elongated span of metal is arranged vertically in between a further one of the first input-output electrode buses and a further one of the second input-output electrode buses.

13. The semiconductor device of claim 8, wherein the first elongated span of metal is formed in a lower-level metallization that is underneath the upper-level metallization layer, and wherein the first elongated span of metal directly connects and merges with each of the field plates.

14. The semiconductor device of claim 13, wherein the gate bus directly overlaps with the first elongated span of metal in the active area, wherein the first elongated span of metal comprises a plurality of openings, and wherein the gate bus is electrically connected with each of the gate electrodes by vertical through-vias that extend through the openings.

15. The semiconductor device of claim 8, wherein the secondary circuit comprises first and second switching devices connected in parallel with the bidirectional switch, wherein the first and second switching devices each comprise elongated gate electrodes and outer terminal electrodes that are arranged as elongated columns within the active area of the semiconductor body, wherein the first elongated span of metal is formed in a lower-level metallization that is underneath the upper-level metallization layer, and wherein the first elongated span of metal directly connects and merges with each of the field plates and the outer terminal electrodes of the first and second switching devices.

16. The semiconductor device of claim 1, wherein the semiconductor device comprises first and second enclosed gate electrode rings immediately adjacent to one another and an enclosed outer electrode ring that at least partially surrounds the first and second enclosed gate electrode rings, wherein the first input-output terminal comprises a first input-output terminal electrode that is arranged within the first enclosed gate electrode ring, wherein the second input-output terminal comprises a second input-output terminal electrode that is arranged within the second enclosed gate electrode ring, and wherein the one or more gate electrodes of the gate structure comprise a central span of the first and second enclosed gate electrode rings in between the first and second input-output terminal electrodes.

17. The semiconductor device of claim 16, further comprising an enclosed outer electrode ring that surrounds the first and second enclosed gate electrode rings, wherein the secondary circuit comprises first and second switching devices connected in series between the first and second input-output terminals of the bidirectional switch, wherein the enclosed outer electrode ring forms a first terminal of the first switching device that is connected with the first input-output terminal of the bidirectional switch and a second terminal of the second switching device that is connected with the second input-output terminal of the bidirectional switch, and wherein the first and second enclosed gate electrode rings form gate electrodes of the first and second switching devices, respectively.

18. The semiconductor device of claim 17, wherein the semiconductor device comprises first and second enclosed field plate rings that are formed in a lower-level metallization and overlap with the first and second enclosed gate electrode rings, respectively, wherein the first and second enclosed field plate rings form the field plate structure of the bidirectional switch, and wherein the quasi-reference potential connection comprises a discrete span of the lower-level metallization that extends across a gap between the first and second enclosed field plate rings and the enclosed outer electrode ring.

19. The semiconductor device of claim 17, wherein the semiconductor device comprises a continuous region of lower-level metallization that is disposed inside of the enclosed outer electrode ring extends over the first and second enclosed gate electrode rings, wherein the continuous region of lower-level metallization forms the field plate structure of the bidirectional switch, and wherein the quasi-reference potential connection comprises the continuous region of lower-level metallization.

20. The semiconductor device of claim 17, wherein the secondary circuit comprises a rectifier device connected between the first node and a second node of the secondary circuit, wherein the rectifier device comprises a third enclosed gate electrode ring disposed outside of the enclosed outer electrode ring, a source terminal electrode column arranged within the third enclosed gate electrode ring, and an enclosed conductive ring formed in a lower-level metallization layer, wherein the enclosed conductive ring is directly connected with the third enclosed gate electrode ring by vertical through-vias.
